(19) United States
(12) Patent Application Publication
(10) Pub. No.: US 2019/0311970 A1
(43) Pub. Date: Oct. 10, 2019

(54) HEAT SINK AND COOLING DEVICE

(71) Applicant: SHOWA DENKO K.K., Tokyo (JP)

(72) Inventor: Kazuhiko MINAMI, Tochigi (JP)

(73) Assignee: SHOWA DENKO K.K., Tokyo (JP)

(21) Appl. No.: 16/307,596

(22) PCT Filed: May 30, 2017
(86) PCT No.: PCT/JP2017/020101

§ 371 Date: Dec. 6, 2018

(30) Foreign Application Priority Data
Jun. 7, 2016 (JP) 2016-113206

(51) Int. Cl. H01L 23/373; H01L 23/367; H01L 21/48; B23P 15/26

(52) U.S. Cl. CPC H01L 23/3733; B23P 15/26; H01L 21/4871; H01L 23/3672

(57) ABSTRACT

A heat sink (1A) is made of a composite material of aluminum and carbon particles (5). A plurality of fin portions (3) is integrally formed on a base plate portion (2) of the heat sink (1A) so as to protrude with respect to the base plate portion (2). The carbon particles (5) present in the fin portion (3) are oriented in the protrusion direction (P) of the fin portion (3) with respect to the base plate portion (2).

### TECHNICAL FIELD

The present invention relates to a heat sink and a cooling device for cooling a heating element such as a heat generating element, and also related to a production method of a heat sink.

### BACKGROUND ART

A heat generating element, such as, e.g., an electronic element, is mounted on a mounting surface of an insulating substrate by being secured by soldering. For the purpose of cooling the heated electronic element, the insulating substrate is secured by soldering, etc., to a cooling surface which is one side surface of the base plate portion of the heat sink in the thickness direction or a cooling surface of a cooling device (for example, see Patent Documents 1 to 4).

A heat sink and a cooling device (including a heat radiator) is required to have a high cooling performance (including a heat radiation performance) in order to assuredly cool a heated electronic element.

### PRIOR ART

### Patent Document

Patent Document 1: Japanese Unexamined Patent Application Publication No. 2014-160764
Patent Document 2: Japanese Unexamined Patent Application Publication No. 2014-160763
Patent Document 3: Japanese Unexamined Patent Application Publication No. 2014-50847
Patent Document 4: Japanese Unexamined Patent Application Publication No. 2013-222909

### SUMMARY OF THE INVENTION

### Problems to be Solved by the Invention

In recent years, as the performance of electronic elements is enhanced and the operating temperature is increased, a higher cooling performance is required for a heat sink and a cooling device.

The present invention has been made in view of the aforementioned technical background, and its purpose is to provide a heat sink and a cooling device having a high cooling performance and a production method of a heat sink. The other purposes and advantages of the present invention will be made apparent from the following preferred embodiments.

### Means for Solving the Problems

The present invention provides the following means.

[1] A heat sink made of a composite material of aluminum and carbon particles,

wherein a plurality of fin portions is integrally formed on a base plate portion so as to protrude with respect to the base plate portion, and

wherein the carbon particles present in the fin portion are oriented in a protrusion direction of the fin portion with respect to the base plate portion.

[2] The heat sink as recited in the aforementioned Item [1], wherein scaly graphite particles are used as the carbon particles.

[3] A cooling device provided with the heat sink as recited in the aforementioned Item [1] or [2].

[4] A production method of a heat sink, comprising: subjecting a forging material composed of a composite material of aluminum and carbon particles to a hot forging process to form the heat sink as recited in the aforementioned Item [1] or [2].

[5] A production method of a heat sink, wherein the heat sink as recited in the aforementioned Item [2] is formed by an extruded article obtained by extruding a billet composed of a composite material of aluminum and carbon particles.

### Effects of the Invention

The present invention provides the following means.

In the aforementioned Item [1], since the carbon particles present in the fin portion of the base plate portion of the heat sink are oriented in the protrusion direction of the fin portion with respect to the base plate portion, the thermal conductivity of the fin portion in the protrusion direction increases. With this, the heat sink has a high cooling performance.

In the aforementioned Item [2], since scaly graphite particles are used as the carbon particles, the cooling performance of the heat sink can be further enhanced.

In the aforementioned Item [3], since the cooling device is provided with the heat sink described in the aforementioned Item [1] or [2], the cooling device has a high cooling performance.

In the aforementioned Item [4], it is possible to assuredly and easily obtain the heat sink described in the aforementioned Item [1] or [2].

In the aforementioned Item [5], it is possible to assuredly and easily obtain the heat sink described in the aforementioned Item [2].

### BRIEF DESCRIPTION OF THE DRAWINGS

FIG. 1 is a cross-sectional view showing a heat sink according to a first embodiment of the present invention together with an insulating substrate.

FIG. 2a is a perspective view of the heat sink.

FIG. 2b is a partially cutaway side view showing the extrusion processing apparatus in a state in which a billet is in the middle of being extruded.

FIG. 3 is a cross-sectional view showing a cooling device provided with the heat sink together with an insulating substrate.

FIG. 4 is a perspective view of a heat sink according to a second embodiment of the present invention.

FIG. 5 is a cross-sectional view showing a state in which a forging material for forming the heat sink is in the middle of being hot forged.

FIG. 6 is a cross-sectional view of a heat sink according to a third embodiment of the present invention.

FIG. 7 is a cross-sectional view of a heat sink according to the fourth embodiment of the present invention.

### EMBODIMENTS FOR CARRYING OUT THE INVENTION

Hereinafter, some embodiments of the present invention will be described with reference to the attached figures.

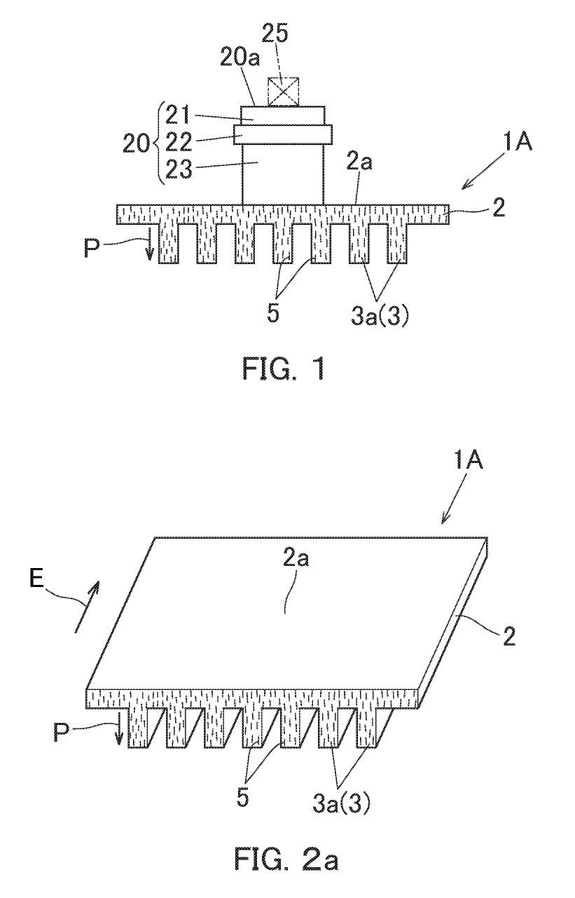

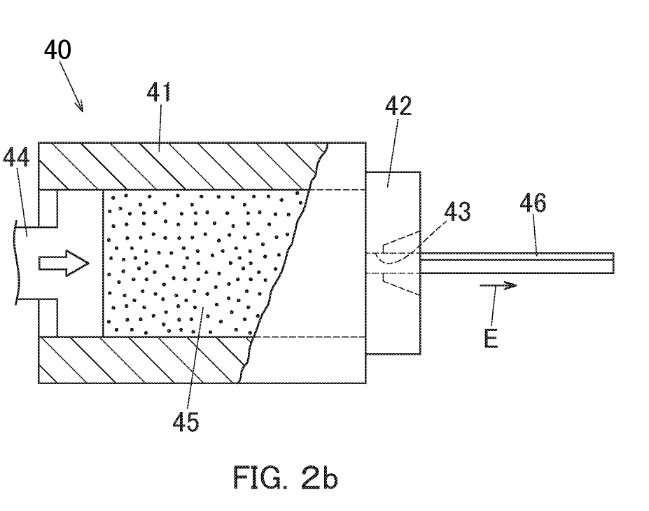

FIG. 1 and FIG. 2 are diagrams for explaining a first embodiment of the present invention.

As shown in FIG. 1, the heat sink 1A according to the first embodiment of the present invention is configured to cool the heat generating element 25 by radiating the heat of the heat generating element (indicated by the two-dot chain line) 25 as a heating element bonded to the mounting surface 20a of the insulating substrate 20 by soldering or the like. As the heat generating element 25, an electronic element, such as, e.g., a semiconductor element, is specifically exemplified.

The insulating substrate 20 is provided with a wiring layer 21 having a mounting surface 20a, an electrical insulating layer 22 made of ceramic, a buffer layer 23 made of metal, and the like. The insulating substrate 20 is formed by integrally bonding these layers 21, 22, and 23 in a stacked manner, and is made of, for example, a DBA substrate or a DBC substrate.

The heat sink 1A is made of a composite material of aluminum and carbon particles 5, and is provided with a base plate portion 2 and a number of fin portions 3 for heat radiation. The carbon particles 5 have anisotropy for thermal conductivity.

Here, in FIG. 1, the carbon particles 5 are depicted in a short line shape. Note that the line direction (longitudinal direction) of the carbon particle 5 depicted in the figure indicates the high thermal conduction direction of the carbon particle 5. The same applies to other figures.

Further, in FIG. 1, in order to make it easy to understand the orientation of the carbon particles 5 (that is, the high thermal conduction direction of the carbon particle 5) present in the heat sink 1A, hatching is omitted on the cross-section of the heat sink 1A. The same is applied to other figures.

The plurality of fin portions 3 are integrally formed on the base plate portion 2 so as to protrude toward at least one side of both sides in the thickness direction with respect to the base plate portion 2.

In this first embodiment, the plurality of fin portions 3 are integrally formed on the base plate portion 2 so as to protrude toward only one side in the thickness direction with respect to the base plate portion 2. Further, each fin portion 3 is integrally formed on the base plate portion 2 continuously in the length direction of the base plate portion 2 (the direction perpendicular to the plane of paper in FIG. 1). Thus, each fin portion 3 is a so-called straight fin portion 3a.

The insulating substrate 20 is bonded by brazing or the like to the cooling surface 2a which is a surface on the side where a number of straight fin portions 3a are not arranged among both surfaces in the thickness direction of the base plate portion 2. The cooling surface 2a of the base plate portion 2 is formed substantially flat.

On the surface of the heat sink 1A, before the insulating substrate 20 is bonded to the cooling surface 2a, a Ni plating layer may be formed in order to improve the solderability and corrosion resistance. The Ni plating layer may be formed by an electroless Ni plating method or an electric Ni plating method.

In the composite material of aluminum and carbon particles 5 which is the material of the heat sink 1A of the first embodiment, although the kind of the carbon particles 5 is not limited, it is preferable that the carbon particles 5 have as high a thermal conductivity as possible and be carbon particles easily composite with aluminum. Specifically, the carbon particles 5 are desirably at least one selected from the group consisting of carbon fibers, carbon nanotubes, graphene, natural graphite particles, and artificial graphite particles. More preferably, the carbon particles 5 are at least one selected from the group consisting of carbon fibers, carbon nanotubes, graphene, and natural graphite particles.

As the carbon fibers, pitch based carbon fibers, PAN based carbon fibers, and the like are suitably used.

As the carbon nanotube, a single layer carbon nanotube, a multilayer carbon nanotube, a vapor phase growth carbon fiber (including VGCF (registered trademark)), or the like is suitably used.

As the graphene, single layer graphene, multilayer graphene and the like are preferably used.

As the natural graphite particles, scaly graphite particles and the like are preferably used.

As the artificial graphite particles, anisotropy graphite particles, pyrolytic graphite particles and the like are suitably used.

The size of the carbon particles 5 is not limited. However, when the carbon particles 5 are carbon fibers, a short carbon fiber is suitably used, and in particular, a short carbon fiber having an average fiber length of 10 μm or more and 2 mm or less is suitably used. When carbon particles 5 are carbon nanotubes, a carbon nanotube having an average length of 1 μm or more and 10 μm or less is particularly preferably used. When the carbon particles 5 are natural graphite particles or artificial graphite particles, natural graphite particles or artificial graphite particles having an average particle diameter of 10 μm or more and 3 mm or less are particularly preferably used.

The type of composite material of aluminum and carbon particles 5 is not limited. For example, the composite material may be a composite material obtained by integrally sintering a plurality of coated foils in which a carbon particles layer is coated on an aluminum foil in a laminated manner (this composite material will be hereinafter referred to as “laminated sintered type composite material material”). Or, the composite material may be a composite material obtained by mixing and sintering aluminum particles (e.g., aluminum powder) and carbon particles (e.g., carbon powder) (for the sake of convenience, hereinafter referred to as “particle sintering type composite material”). In all of these composite materials, aluminum is used as a matrix metal and carbon particles 5 are used as a filler. A large number of carbon particles 5 are dispersed in aluminum throughout the composite material.

In the heat sink 1A, the carbon particles 5 present in each straight fin portion 3a are oriented in the protrusion direction P of the straight fin portion 3a with respect to the base plate portion 2. Therefore, the high thermal conduction direction of the carbon particles 5 present in each straight fin portion 3a is oriented in the protrusion direction P of the straight fin portion 3a with respect to the base plate portion 2.

In the first embodiment, as the carbon particle 5, carbon particles excellent in thermal conductivity in the direction of the particle surface are used. That is, carbon particles in which the direction of high thermal conductivity is the plane direction of the grain is used. Specifically, scaly graphite particles are used as such carbon particles 5.

The thermal conductivity of scaly graphite particle in the planar direction is significantly higher than the thermal conductivity in the thickness direction. Therefore, in the first embodiment, the plane direction of the scaly graphite particles present in each straight fin portion 3a is oriented in the protrusion direction P of the straight fin portion 3a. With this, the high thermal conduction direction of the scaly graphite particle in each straight fin portion 3a is oriented in the protrusion direction P of the straight fin portion 3a.

The heat sink 1A of the first embodiment is formed by an extruded article. The symbol “E” in FIG. 2a shows the extrusion direction.

The production method of the heat sink 1A of the first embodiment is as follows.

As shown in FIG. 2b, a substantially columnar billet (i.e., extrusion material) 45 composed of a composite material of aluminum and scaly graphite particles as carbon particles 5 is extruded by an extrusion processing apparatus 40. Thus, an elongated an extruded article 46 having the same cross-sectional shape as that of the heat sink 1A is obtained. Note that in FIG. 2b, dot hatching is depicted on the billet 45 to make it easy to distinguish the billet 45 from other members.

The extrusion processing apparatus 40 is provided with a container 41, an extrusion die 42, a stem 44, etc. The extrusion die 42 is provided with an extrusion hole 43 having the same cross-sectional shape as that of the heat sink 1A. When extruding the billet 45, the billet 45 is loaded into the container 41. The billet 45 is heated to a predetermined temperature as necessary. Then, the billet 45 is pressed in the extrusion direction E by the stem 44 and passes through the extrusion hole 43 of the extrusion die 42. With this, the long extruded article 46 described above is obtained.

Next, the extruded article 46 is cut into a predetermined length, so the heat sink 1A formed by the extruded article 46 shown in FIG. 2a is obtained. In the heat sink 1A, the continuous direction of the straight fin portion 3a coincides with the extrusion direction E of the extruded article 46.

As described above, by forming the heat sink 1A with the an extruded article 46 obtained by extruding the billet 45 made of a composite material of aluminum and scaly graphite particles as carbon particles 5, the scaly graphite particles as carbon particles 5 present in each straight fin portion 3a can be assuredly oriented in the protrusion direction P of the straight fin portion 3a and the heat sink 1A having such a large number of straight fin portions 3a can be assuredly and easily produced.

The billet 45 may be made of the above-described laminated sintered type composite material. The billet 45 may be made of the above-described particle sintered type composite material. The billet 45 may be other composite materials of aluminum and carbon particles.

According to the heat sink 1A of the first embodiment, since the carbon particles 5 present in each straight fin portion 3a are oriented in the protrusion direction P of the straight fin portion 3a with respect to the base plate portion 2, the thermal conductivity of each straight fin portion 3a in the protrusion direction P is high. Therefore, the heat sink 1A has a high cooling performance (including a heat radiation performance).

Furthermore, since scaly graphite particles are used as carbon particles 5, the heat sink 1A has a very high cooling performance.

Here, if, as carbon particles 5, not carbon particles such as scaly graphite particles in which the direction of high thermal conductivity is the plane direction of the particle but carbon particles (e.g., carbon fibers) in which the direction of high thermal conductivity is only one direction of the particle is used, when the heat sink is formed by an extruded article obtained by extruding a billet composed of aluminum and the carbon particles, the carbon particles present in each straight fin portion tend to be difficult to orient in the protrusion direction P of the straight fin portion. Therefore, in the case of forming a heat sink with an extruded article, it is particularly desirable to use carbon particles (e.g., scaly graphite particles) whose direction of high thermal conductivity is the plane direction of the particle as the carbon particles 5. By using such carbon particles, even when a heat sink is formed by an extruded article, it is possible to assuredly orient the carbon particles 5 in the protrusion direction P of the straight fin portion 3a.

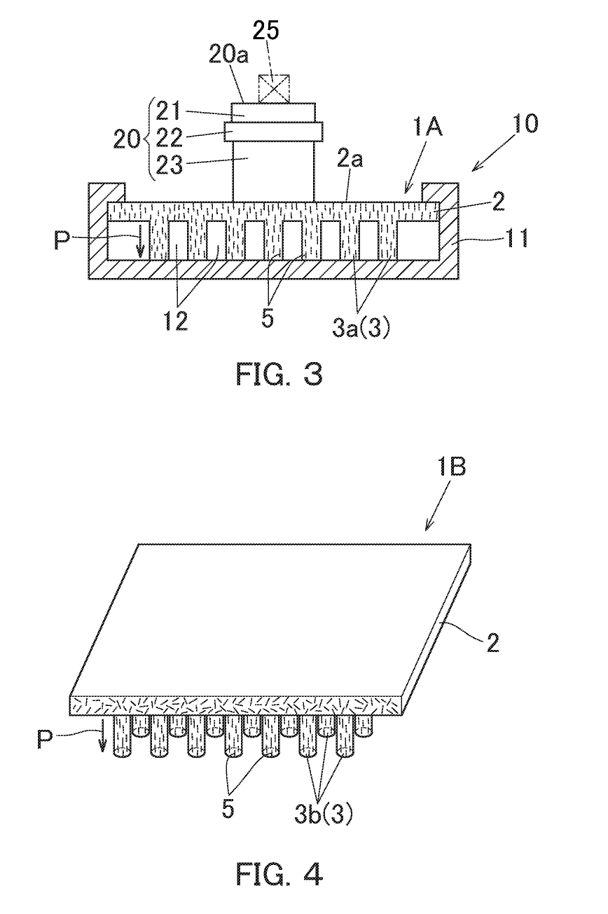

The cooling device (including a heat radiator) 10 shown in FIG. 3 is provided with the heat sink 1A of the first embodiment shown in FIG. 1 and FIG. 2 and the housing body 11.

The housing body 11 is made of, e.g., metal, and has an opening portion. The heat sink 1A is arranged in the housing body 11, and the opening of the housing body 11 is closed by the base plate portion 2 of the heat sink 1A. The inside of the housing body 11 is partitioned by a number of straight fin portions 3a of the heat sink 1A, so flow paths 12 through which cooling fluids (e.g., coolants) flow are formed inside the housing body 11. In this state, the heat sink 1A is integrally joined to the housing body 11 by brazing. Thus, the cooling device 10 is produced.

Therefore, in the cooling device 10, the heat sink 1A is used as a lid in which the base plate portion 2 closes the opening portion of the housing body 11 and a large number of straight fin portions 3a are used as partition wall portions (inner fin portions) forming the cooling fluid flow path 12 inside the housing body 11.

The insulating substrate 20 is joined to the cooling surface 2a of the base plate portion 2 of the heat sink 1A as a cooling surface of the cooling device 10 by brazing or the like.

Note that on the cooling surface 2a of the base plate portion 2 of the heat sink 1A, a double sided brazing sheet for brazing the insulating substrate 20 to the cooling surface 2a may be arranged. Also, the housing body 11 may be made of an inner brazing sheet to braze the heat sink 1A to the housing body 11.

In the heat sink 1B according to the second embodiment of the present invention shown in FIG. 4, each fin portion 3 is formed in a pin-shape, that is, it is formed as a pin fin portion 3b. Then, a large number of pin fin portions 3b are integrally formed on the base plate portion 2 in a state of protruding in a pin-shape only on one side in the thickness direction with respect to the base plate portion 2. The cross-sectional shape of each pin fin portion 3b is substantially circular.

In the composite material of aluminum and carbon particles 5 which is the material of the heat sink 1B of the second embodiment, as the carbon particles 5, at least one selected from the group consisting of carbon fibers, carbon nanotubes, graphene, natural graphite particles, and artificial graphite particles is used.

The carbon particles 5 present in each pin fin portion 3b are oriented in the protrusion direction P of the pin fin portion 3b with respect to the base plate portion 2. Therefore, the high thermal conduction direction of the carbon particles 5 present in each pin fin portion 3b is oriented in the protrusion direction P of the pin fin portion 3b with respect to the base plate portion 2.

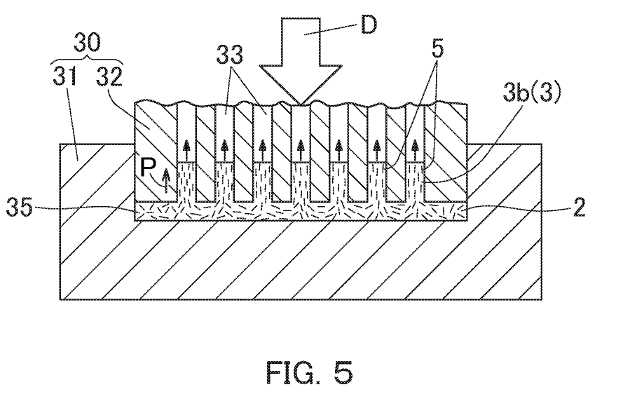

As shown in FIG. 5, this heat sink 1B is produced by, subjecting a substantially plate-like forging material 35 made of a composite material of aluminum and carbon particles 5 to a hot forging process (more specifically, a hot die forging process) using a hot forging process apparatus equipped with a hot forging processing die 30.

The die 30 is provided with a die main body 31 and a punch 32 for pressing a forging material 35 disposed in the die main body 31. The symbol “D” in FIG. 5 indicates the pressing direction of the forging material 35 by the punch 32. A plurality of fin portion forming holes 33 for forming the pin fin portions 3b are provided at the tip portion of the punch 32.

The material of the forging material 35 plastically flows so that the material of the forging material 35 enters into each fin portion forming hole 33 of the punch 32 by being pressed by the punch 32 in the die main body 31. In accordance with this material flow, the orientation of the carbon particle 5 in the material entering into each fin portion formation hole 33 is aligned with the extending direction of each fin portion formation hole 33. As a result, in the heat sink 1B, the carbon particles 5 present in each pin fin portion 3b are oriented in the protrusion direction P of the pin fin portion 3b (i.e., the high thermal conduction direction of the carbon particles 5 in each pin fin portion 3b is oriented in the protrusion direction P of the pin fin portion 3b).

As described above, by forming the heat sink by the production method by a hot forging process, it is possible to assuredly orient the carbon particles 5 present in each pin fin portion 3b in the protrusion direction P of the pin fin portion 3b, and it is also possible to assuredly and easily produce the heat sink 1B having such a large number of pin fin portions 3b.

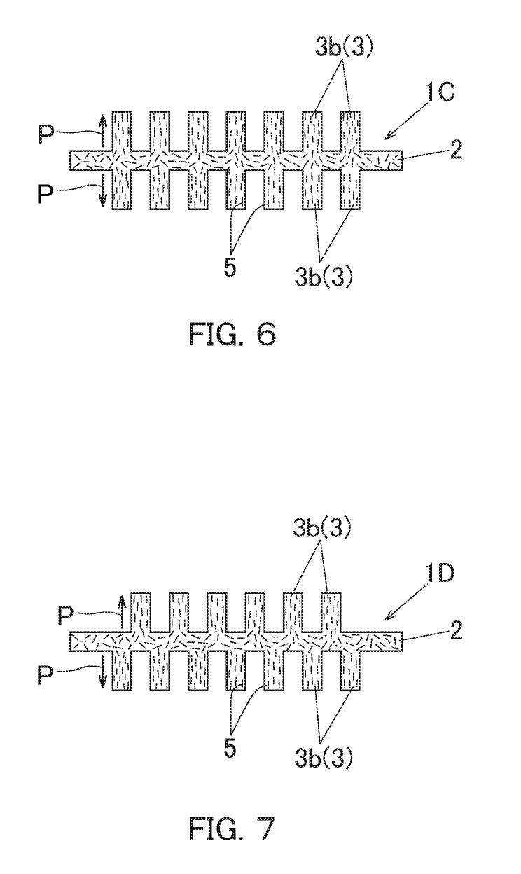

In the heat sink 1C according to the third embodiment of the present invention shown in FIG. 6, each fin portion 3 is formed in a pin-shape, that is, it is formed into a pin fin portion 3b. The plurality of pin fin portions 3b is integrally formed on the base plate portion 2 so as to protrude toward both sides in the thickness direction with respect to the base plate portion 2. The position of the pin fin portion 3b protruding on one side of the base plate portion 2 in the thickness direction and the position of the pin fin portion 3b protruding on the other side of the base plate portion 2 in the thickness direction coincide each other in the width direction (the left-right direction in FIG. 6) of the base plate portion 2.

In the heat sink 1D according to the fourth embodiment of the present invention shown in FIG. 7, each fin portion 3 is formed in a pin-shape, that is, it is formed into a pin fin portion 3b in the same manner as the heat sink 1C in the aforementioned third embodiment. The plurality of pin fin portions 3b is integrally formed on the base plate portion 2 so as to protrude toward both sides in the thickness direction with respect to the base plate portion 2. However, the position of the pin fin portion 3b protruding on one side of the base plate portion 2 in the thickness direction and the position of the pin fin portion 3b protruding on the other side of the base plate portion 2 in the thickness direction are displaced in the width direction (left-right direction in FIG. 7) of the base plate portion 2.

In the heat sinks 1C and 1D of the third and fourth embodiments, as the carbon particles 5, at least one selected from the group consisting of carbon fibers, carbon nanotubes, graphene, natural graphite particles, and artificial graphite particles is used.

In each of the heat sinks 1B to 1D according to the second to fourth embodiments described above, since the carbon particles 5 present in each pin fin portion 3b are oriented in the protrusion direction P of the pin fin portion 3b with respect to the base plate portion, the thermal conductivity of the protrusion direction P of each pin fin portion 3b is high. Therefore, the heat sinks 1B to 1D have a high cooling performance.

These heat sinks 1B to 1D may be used by being disposed within the housing body of the cooling device, or may be used without being disposed in the housing body of the cooling device.

Although some embodiments of the present invention are described above, the present invention is not limited to these aforementioned embodiments, and various modifications can be made within the scope not departing from the gist of the present invention.

Like the heat sink 1A of the first embodiment, the heat sink having a plurality of straight fin portions as a plurality of fin portions is particularly preferably formed by an extruded article like in the first embodiment. However, in the present invention, such a heat sink may be formed by, for example, a hot forging process (e.g., hot die forging process).

### EXAMPLE

Next, specific examples of the present invention will be described below. It should be noted, however, that the present invention is not limited to the examples described below.

### Example 1

The heat sink 1A of the first embodiment shown in FIG. 1 was manufactured as follows.

A billet 45 made of a composite material of aluminum and scaly graphite powder as carbon particles 5 was prepared. The composite material was produced by mixing and sintering aluminum powder and scaly graphite powder.

Subsequently, by extrusion the billet 45, an elongated extruded article 46 having the same cross-sectional shape as the cross-sectional shape of the desired heat sink 1A was obtained. Then, by cutting the extruded article 46 into a predetermined length, a heat sink 1A was obtained.

The cooling performance of the obtained heat sink 1A was superior to that of an aluminum heat sink.

### Example 2

The heat sink 1B of the second embodiment shown in FIG. 4 was produced as follows.

A plate-like forging material 35 made of a composite material of aluminum and short carbon fiber as carbon particles 5 was prepared. The composite material was produced by mixing and sintering aluminum powder and short carbon fibers.

Next, a heat sink 1B was obtained by subjecting the forging material 35 to a hot die forging process.

The cooling performance of the obtained heat sink 1B was superior to that of an aluminum heat sink.

The present application claims priority to Japanese Patent Application No. 2016-113206 filed on Jun. 7, 2016, the entire disclosure of which is incorporated herein by reference in its entirety.

It should be understood that the terms and expressions used herein are used for explanation and have no intention to be used to construe in a limited manner, do not eliminate any equivalents of features shown and mentioned herein, and allow various modifications falling within the claimed scope of the present invention.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. Limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.”

### INDUSTRIAL APPLICABILITY

The present invention is applicable to a heat sink and a cooling device for cooling a heating element such as a heat generating element, and also applicable to a production method of a heat sink.

### DESCRIPTION OF REFERENCE SYMBOLS

1A to 1D heat sink
2 base plate portion
3 fin portion
3a straight fin portion
3b pin fin portion
5 carbon particles
10 cooling device
20 insulating substrate
30 hot forging die
35 forging material
45 billet
46 extruded article
P protrusion direction of a fin portion

1. A heat sink made of a composite material of aluminum and carbon particles,
wherein a plurality of fin portions is integrally formed on a base plate portion so as to protrude with respect to the base plate portion, and
wherein the carbon particles present in the fin portion are oriented in a protrusion direction of the fin portion with respect to the base plate portion.

2. The heat sink as recited in claim 1,
wherein scaly graphite particles are used as the carbon particles.

3. A cooling device provided with the heat sink as recited in claim 1.

4. A production method of a heat sink, comprising:
subjecting a forging material composed of a composite material of aluminum and carbon particles to a hot forging process to form the heat sink as recited in claim 1.

5. A production method of a heat sink,
wherein the heat sink as recited in claim 2 is formed by an extruded article obtained by extruding a billet composed of a composite material of aluminum and carbon particles.
